(19) United States
(12) Patent Application Publication
(10) Pub. No.: US 2008/0204114 A1
(43) Pub. Date: Aug. 28, 2008

(54) TRANSMISSION GATE SWITCH, SYSTEM USING THE SAME, AND DATA INPUT/OUTPUT METHOD THEREOF

(75) Inventors: Ki-Hong Kim, Suwon-si (KR); Jong-Seok Kim, Yongin-si (KR); Jin Ho Oh, Yongin-si (KR); Choon-Oh Lee, Cheonan-si (KR)

Correspondence Address: STANZIONE & KIM, LLP, 919 18TH STREET, N.W., SUITE 440, WASHINGTON, DC, 20006, US

(73) Assignee: Samsung Electronics Co., Ltd., Suwon-si (KR)

(21) Appl. No.: 12/035,585

(22) Filed: Feb. 22, 2008

(30) Foreign Application Priority Data
Feb. 22, 2007 (KR) 2007-17989

(51) Int. Cl. H03K 17/687; H03K 17/00

(52) U.S. Cl. 327/437; 327/365

(57) ABSTRACT

A transmission gate switch includes a switching unit to conduct a switching operation between first and second nodes in response to a switching signal, and an isolation unit to prevent the switching unit from being turned on by a negative swing of the first or second node while the switching unit is being turned off.

### CROSS-REFERENCE TO RELATED APPLICATIONS

This U.S. non-provisional patent application claims priority under 35 U.S.C. § 119 of Korean Patent Application No. 10-2007-17989 filed on Feb. 22, 2007, the entire contents of which are incorporated herein by reference.

### BACKGROUND OF THE INVENTION

1. Field of the Invention

The present general inventive concept disclosed herein relates to transmission gate switches. More particularly, the present general inventive concept disclosed herein is concerned with transmission gates inhibiting negative swings, a system including these transmission gates, and a method of inputting/outputting data in the system.

2. Description of the Related Art

FIG. 1 is a circuit diagram of a general transmission gate switch 10. Referring to FIG. 1, the transmission gate switch 10 includes a PMOS transistor PM and an NMOS transistor NM.

When switching signals SWIN and SWINB are logically high and low levels, respectively, the NMOS and PMOS transistors NM and PM are turned on. Then, a node A is electrically connected to a node B.

In contrast, if the switching signals SWIN and SWINB are logically low and high levels, respectively, the NMOS and PMOS transistors NM and PM are turned off to electrically isolate the node A from the node B.

However, there is a problem that the transmission gate switch 10 is insufficient in operation for the electrical isolation to the nodes A and B while a signal input to the node B swings in the negative direction. For instance, when the switching signal SWIN is charged with a voltage of ‘0’ (low level), the transmission gate switch 10 must be turned off. But, the NMOS transistor NM is inadvertently turned on because the negative voltage is applied to the node B.

### SUMMARY OF THE INVENTION

The present general inventive concept provides a transmission gate switch normally operating even in a negative swing mode, a system including the negative gate switches, and a method of inputting/outputting data in the system.

Additional aspects and utilities of the present general inventive concept will be set forth in part in the description which follows and, in part, will be obvious from the description, or may be learned by practice of the general inventive concept.

The foregoing and/or other aspects and utilities of the present general inventive concept are achieved by providing a transmission gate switch including: a switching unit to conduct a switching operation between first and second nodes in response to a switching signal; and an isolation unit to prevent the switching unit from being turned on by a negative swing of the first or second node while the switching unit is being turned off.

In an embodiment, the switching unit is formed in a complementary metal-oxide-semiconductor structure.

In an embodiment, the switching unit includes: a first NMOS transistor including a drain connected to the first node, and a gate to which a first switching signal is applied; and a first PMOS transistor including a source connected to the first node, a drain connected to the second node, and a gate to which a second switching signal is applied. The first and second switching signals are complementary to each other and the source of the first NMOS transistor is connected or disconnected through the isolation unit.

In an embodiment, while the switching unit is being turned off, the isolation unit electrically isolates the source of the first NMOS transistor from the second node.

In an embodiment, if the switching unit is turned off and a positive signal is applied to the second node, the isolation unit electrically isolates the source of the first NMOS transistor from the second node.

In an embodiment, if the switching unit is turned off and a negative signal is applied to the second node, the isolation unit electrically isolates the source of the first NMOS transistor from the second node.

In an embodiment, the isolation unit includes: a second NMOS transistor including a drain connected to the source of the first NMOS transistor, and a source connected to the second node; a third NMOS transistor including a drain connected to a gate of the second NMOS transistor, a source connected to the second node, and a gate to which the second switching signal is applied; and a second PMOS transistor including a source connected to the gate of the second NMOS transistor, a drain to which the first switching signal is applied, and a gate to which the second switching signal is applied. The second and third NMOS transistors are connected to the second node through a substrate.

In an embodiment, the second and third NMOS transistors are formed in a triple well structure.

The foregoing and/or other aspects and utilities of the present general inventive concept can also be achieved by providing a system including: a USB device; an audio amplifier; an input/output port shared by the USB device and the audio amplifier; and a switch block to determine whether to connect the input/output port with one of the USB device and the audio amplifier. The switch block connects the audio amplifier to the input/output port during turn-off duration and is prevented from being a turned on by a negative signal input to and output from the audio amplifier.

In an embodiment, the switch block includes transmission gate switches. Each transmission gate switch includes: a switching unit to conduct a switching operation between first and second nodes in response to a switching signal; and an isolation unit to prevent the switching unit from being turned on by a negative swing of the first or second node while the switching unit is being turned off.

In an embodiment, the switching unit is formed in a complementary metal-oxide-semiconductor structure.

In an embodiment, the switching unit includes: a first NMOS transistor including a drain connected to the first node, and a gate to which a first switching signal is applied; and a first PMOS transistor including a source connected to the first node, a drain connected to the second node, and a gate to which a second switching signal is applied. The first and second switching signals are complementary to each other and the source of the first NMOS transistor is connected or disconnected through the isolation unit.

In an embodiment, while the switching unit is being turned off, the isolation unit electrically isolates the source of the first NMOS transistor from the second node.

In an embodiment, if the switching unit is turned off and a positive signal is applied to the second node, the isolation unit electrically isolates the source of the first NMOS transistor from the second node.

In an embodiment, if the switching unit is turned off and a negative signal is applied to the second node, the isolation unit electrically isolates the source of the first NMOS transistor from the second node.

In an embodiment, the isolation unit includes: a second NMOS transistor including a drain connected to the source of the first NMOS transistor, and a source connected to the second node; a third NMOS transistor including a drain connected to a gate of the second NMOS transistor, a source connected to the second node, and a gate to which the second switching signal is applied; and a second PMOS transistor including a source connected to the gate of the second NMOS transistor, a drain to which the first switching signal is applied, and a gate to which the second switching signal is applied. The second and third NMOS transistors are connected to the second node through a substrate.

In an embodiment, the second and third NMOS transistors are formed in a triple well structure.

The foregoing and/or other aspects and utilities of the present general inventive concept can also be achieved by providing a data input/output method of a system having a USB device and an audio amplifier that share an input/output port. This method includes: connecting the input/output port to one of the USB device and the audio amplifier; connecting the input/output port to the audio amplifier and inputting/outputting data; and preventing an input/output signal of the audio amplifier from being transferred to the USB device while inputting/outputting the data.

In an embodiment, the system includes a switch block to determine whether to connect the input/output port with one of the USB device and the audio amplifier and to prevent an input/output signal of the audio amplifier from being transferred to the USB device.

In an embodiment, the switch block connects the input/output port to the audio amplifier in a turn-off duration and is prevented from being turned on by a negative signal input to and output from the audio amplifier.

A further understanding of the nature and advantages of the present general inventive concept herein may be realized by reference to the remaining portions of the specification and the attached drawings.

### BRIEF DESCRIPTION OF THE DRAWINGS

These and/or other aspects and utilities of the present general inventive concept will become apparent and more readily appreciated from the following description of the embodiments, taken in conjunction with the accompanying drawings of which:

FIG. 1 is a circuit diagram of a general transmission gate switch;

FIG. 2 is a circuit diagram of a transmission gate switch according to an embodiment of the present general inventive concept;

FIG. 3 is a block diagram of a system using the transmission gate switch according to an embodiment of the present general inventive concept;

FIGS. 4A through 4C are graphic diagrams illustrating simulation results when the switch block of the system illustrated in FIG. 3 is turned off;

FIG. 5 is a graphic diagram illustrating eye patterns of the data buses of the system illustrated in FIG. 3; and

FIG. 6 is a graphic diagram illustrating a data pattern input/output into/from the USB device of the system illustrated in FIG. 3.

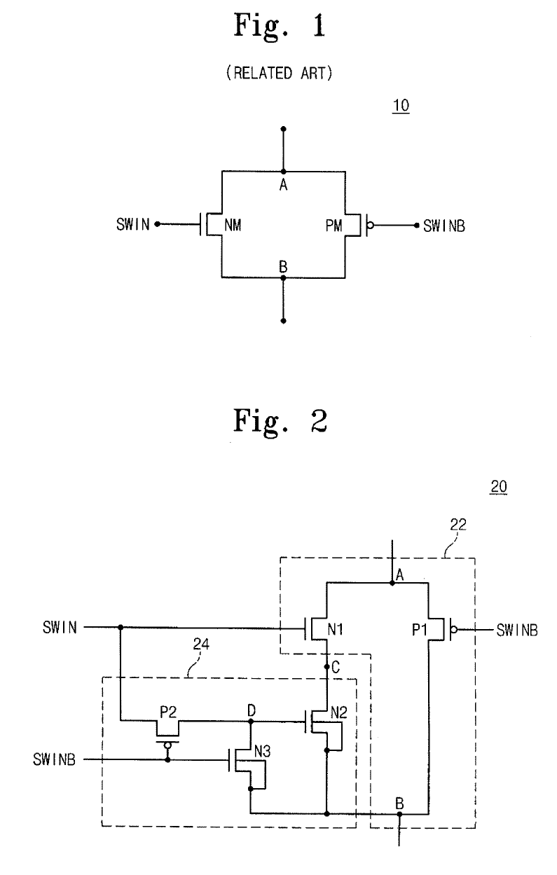

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept by referring to the figures.

FIG. 2 is a circuit diagram of a transmission gate switch 20 according to an embodiment of the present general inventive concept. Referring to FIG. 2, the transmission gate switch 20 includes a switching unit 22 and an isolation unit 24. The isolation unit 24 of the transmission gate unit 20 functions to inhibit the switching unit 22 from being turned on when a negative signal is applied to a node B.

The switching unit 22 includes a PMOS transistor P1 and an NMOS transistor N1. The PMOS transistor P1 is formed of a source connected to a node A, a drain connected to the node B, and a gate to which a switching signal SWINB is applied. The NMOS transistor N1 is formed of a drain connected to the node A, and a gate to which a switching signal SWIN is applied. The switching signals SWIN and SWINB are logically complementary to each other.

When the switching signals SWIN and SWINB are logically high and low levels, respectively, the PMOS and NMOS transistors P1 and N1 are both turned on. Then, the node A is electrically connected to the node B. Otherwise, when the switching signals SWIN and SWINB are logically low and high levels, respectively, the PMOS and NMOS transistors P1 and N1 are both turned off. Then, the node A is electrically isolated from the node B.

The isolation unit 24 includes a PMOS transistor P2 and NMOS transistors N2 and N3. When the switching signals SWIN and SWINB are logically low and high levels, respectively, the isolation unit 24 electrically disconnects the node A with the node B even if a negative signal is applied to the node B.

The PMOS transistor P2 is formed of a source connected to a node D, a drain to which the switching signal SWIN is applied, and a gate to which the switching signal SWINB is applied. The NMOS transistor N2 is formed of a drain connected to a node C, a source connected to the node B, and a gate connected to the node D. The substrate of the NMOS transistor N2 is connected to the source of the NMOS transistor N2, i.e., the node B. The NMOS transistor N3 is formed of a drain connected to the node D, a source connected to the node B, and a gate to which the switching signal SWINB is applied. The substrate of the NMOS transistor N3 is connected to the source of the NMOS transistor N3, i.e., the node B.

The NMOS transistors N2 and N3 are formed in triple well structure. This structure is helpful in rendering the body bias of the NMOS transistors N2 and N3 to be negative. By the triple well structure, a body contact is connected to the sources.

A switching operation of the transmission gate switch 20 according to the present invention will be described hereinafter.

In an isolation mode of the switch, the switching signals SWIN and SWINB are generated in logically low and high levels, respectively. Thereby, the PMOS and NMOS transistors P1 and N1 of the switching unit 22 are all turned off.

The isolation unit 24 conducts its isolating operation when a negative or positive signal is applied to the node B, as follows.

First, when a negative signal is applied to the node B, the isolation unit 24 inhibits the NMOS transistor N1 from being turned on by the negative voltage of the node B. In detail, the PMOS transistor P2 of the isolation unit 24 is turned off while the NMOS transistor N3 is turned on. Then, the node B is electrically connected to the node D. As the negative voltage of the node B is applied to the gate of the NMOS transistor N2, the NMOS transistor N2 is turned off. Thus, the node A is electrically isolated from the node B.

Next, when a positive signal is applied to the node B, the isolation unit 24 electrically disconnects the node A from the node B. In detail, the PMOS transistor P2 of the isolation unit 24 is turned off while the NMOS transistor N3 is turned on. Then, the node B is electrically connected to the node D. If the positive voltage is applied to the node B and the drain of the NMOS transistor N2, i.e., the node C, is lower than the node B in voltage level, the NMOS transistor N2 can be turned on. But, since the NMOS transistor N1 of the switching unit 22 is turned off, the node A is electrically isolated from the node B.

The transmission gate switch 20 according to the present embodiment is turned on through the following procedure. When the switching signals SWIN and SWINB are applied thereto in logically high and low levels, respectively, the PMOS and NMOS transistors of the switching unit 22 are all turned on. On the other hand, in the isolation unit 24, the PMOS transistor P2 is turned on while the NMOS transistor N3 is turned off. Responding to the turn-on of the PMOS transistor P2, the NMOS transistor N2 is turned on to electrically connected the node A with the node B.

The transmission gate switch 20 of the present embodiment has a function of preventing itself from an inadvertent turn-on due to a negative swing when it is being turned off. In other words, the transmission gate switch 20 according to the present embodiment is able to inhibit a negative swing in operation.

The transmission gate switch 20 is applicable to a system that needs to prevent the negative swing.

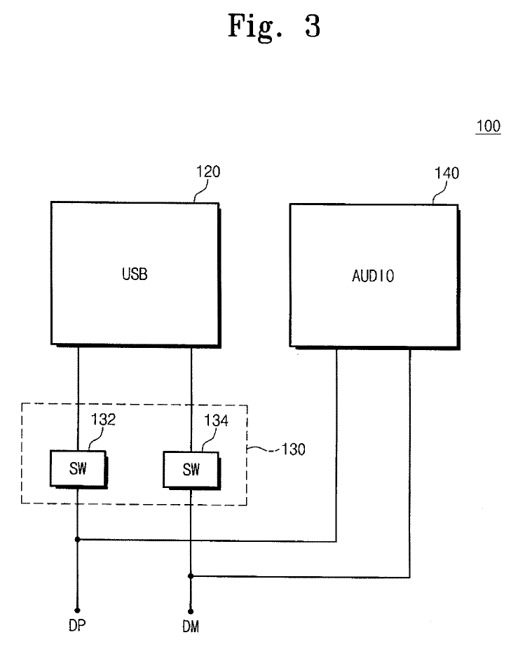

FIG. 3 is a block diagram of a system 100 using the transmission gate switch 20 according to an embodiment of the present general inventive concept. Referring to FIG. 3, the system 100 includes a universal-serial-bus (USB) device 120, a switch block 130, and an audio amplifier 140. In the system 100 according to the present embodiment, the USB device 120 and the audio amplifier 140 operate by sharing data input/output ports. The audio amplifier 140 utilizes first and second data buses DP and DM as input/output ports. For this use of input/output ports, the switch block 130 is employed in the system 100. If the switch block 130 is turned on, the first and second data buses DP and DM act as the input/output ports for the USB device 120. Otherwise, if the switch block 130 is turned off, the first and second data buses DP and DM act as the input/output ports for the audio amplifier 140.

During this, the switch block 130 is required to interrupt a negative swing while it is being turned off. Thus, switches 132 and 134 may be made up with the transmission gate switch 20 illustrated in FIG. 2.

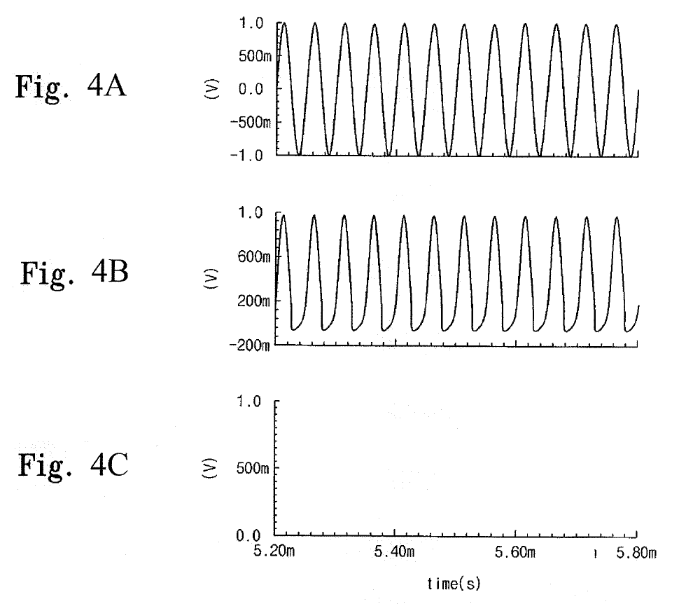

FIGS. 4A through 4C are graphic diagrams illustrating simulation results when the switch block 130 of the system 100 illustrated in FIG. 3 is turned off. FIGS. 4A, 4B, and 4C illustrate voltages of the nodes B, C, and A, respectively. Referring to FIGS. 4A through 4C, it can be seen that the switches 132 and 134 of the system 100 are completely turned off when a signal is swinging in the range from −1.0V to 1.0V.

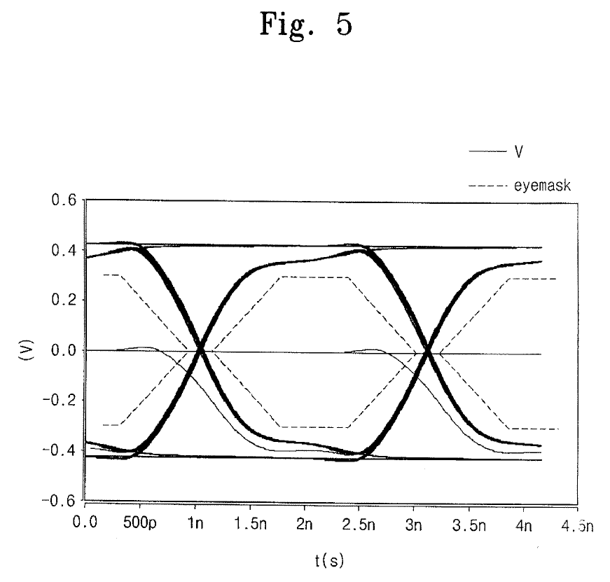

FIG. 5 is a graphic diagram illustrating eye patterns of the data buses DM and DP of the system 100 illustrated in FIG. 3. The system 100 of the present embodiment includes the switch block 130. Referring to FIG. 5, the switches 132 and 134 of the switch block 130 are structured of loading capacitors, operating to be near the eye mask by increasing rising and falling times. The switches 132 and 134 according to the present embodiment are normally operable without trouble, not violating the eye mask.

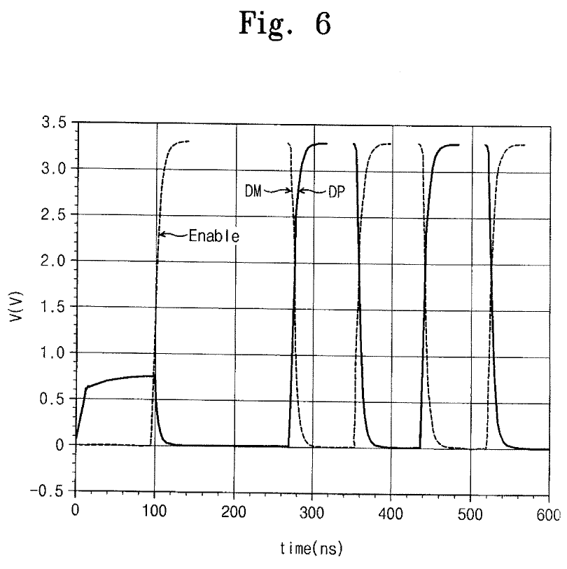

FIG. 6 is a graphic diagram illustrating a data pattern input/output into/from the USB device 120 of the system 100 illustrated in FIG. 3. Referring to FIG. 6, it can be seen that data are operating normally after the USB device 120 is enabled.

The system 100 of the present embodiment operates with sharing the input/output ports by the USB device 120 and the audio amplifier 140, which is as much effective in reducing a circuit area of the system.

The system 100 may be further include another switch block (not shown) that is provided to the audio amplifier 140. The switch block of the audio amplifier is required to be operable in negative swing.

As aforementioned, the embodiments of the present general inventive concept provide a transmission gate switch, a system including the transmission gate switch, and a data input/output method thereof, preventing an inadvertent turn-on of the switch due to a negative swing while the switch is being turned on.

The present general inventive concept can also be embodied as computer-readable codes on a computer-readable recording medium. The computer-readable recording medium is any data storage device that can store data which can be thereafter read by a computer system. Examples of the computer-readable recording media include read-only memory (ROM), random-access memory (RAM), CD-ROMs, magnetic tapes, floppy disks, optical data storage devices, and carrier waves (such as data transmission through the Internet). The computer-readable recording medium can also be distributed over network-coupled computer systems so that the computer-readable code is stored and executed in a distributed fashion. Also, functional programs, codes, and code segments to accomplish the present general inventive concept can be easily construed by programmers skilled in the art to which the present general inventive concept pertains.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A transmission gate switch comprising:
a switching unit to conduct a switching operation between first and second nodes in response to a switching signal; and
an isolation unit to prevent the switching unit from being turned on by a negative swing of the first or second node while the switching unit is being turned off.

2. The transmission gate switch as set forth in claim 1, wherein the switching unit is formed in a complementary metal-oxide-semiconductor structure.

3. The transmission gate switch as set forth in claim 2, wherein the switching unit comprises:
a first NMOS transistor including a drain connected to the first node, and a gate to which a first switching signal is applied; and
a first PMOS transistor including a source connected to the first node, a drain connected to the second node, and a gate to which a second switching signal is applied,
wherein the first and second switching signals are complementary to each other,
wherein the source of the first NMOS transistor is connected or disconnected through the isolation unit.

4. The transmission gate switch as set forth in claim 3, wherein while the switching unit is being turned off, the isolation unit electrically isolates the source of the first NMOS transistor from the second node.

5. The transmission gate switch as set forth in claim 3, wherein if the switching unit is turned off and a positive signal is applied to the second node, the isolation unit electrically isolates the source of the first NMOS transistor from the second node.

6. The transmission gate switch as set forth in claim 3, wherein if the switching unit is turned off and a negative signal is applied to the second node, the isolation unit electrically isolates the source of the first NMOS transistor from the second node.

7. The transmission gate switch as set forth in claim 6, wherein the isolation unit comprises:
a second NMOS transistor including a drain connected to the source of the first NMOS transistor, and a source connected to the second node;
a third NMOS transistor including a drain connected to a gate of the second NMOS transistor, a source connected to the second node, and a gate to which the second switching signal is applied; and
a second PMOS transistor including a source connected to the gate of the second NMOS transistor, a drain to which the first switching signal is applied, and a gate to which the second switching signal is applied,
wherein the second and third NMOS transistors are connected to the second node through a substrate.

8. The transmission gate switch as set forth in claim 7, wherein the second and third NMOS transistors are formed in a triple well structure.

9. A system comprising:
a USB device;
an audio amplifier;
an input/output port shared by the USB device and the audio amplifier; and
a switch block to determine whether to connect the input/output port with one of the USB device and the audio amplifier,
wherein the switch block connects the audio amplifier to the input/output port during a turn-off duration and is prevented from being turned on by a negative signal input to and output from the audio amplifier.

10. The system as set forth in claim 9, wherein the switch block comprises transmission gate switches,
wherein each transmission gate switch comprises:
a switching unit to conduct a switching operation between first and second nodes in response to a switching signal; and
an isolation unit to prevent the switching unit from being turned on by a negative swing of the first or second node while the switching unit is being turned off.

11. The system as set forth in claim 10, wherein the switching unit is formed in a complementary metal-oxide-semiconductor structure.

12. The system as set forth in claim 11, wherein the switching unit comprises:
a first NMOS transistor including a drain connected to the first node, and a gate to which a first switching signal is applied; and
a first PMOS transistor including a source connected to the first node, a drain connected to the second node, and a gate to which a second switching signal is applied,
wherein the first and second switching signals are complementary to each other,
wherein the source of the first NMOS transistor is connected or disconnected through the isolation unit.

13. The system as set forth in claim 12, wherein while the switching unit is being turned off, the isolation unit electrically isolates the source of the first NMOS transistor from the second node.

14. The system as set forth in claim 12, wherein if the switching unit is turned off and a positive signal is applied to the second node, the isolation unit electrically isolates the source of the first NMOS transistor from the second node.

15. The system as set forth in claim 12, wherein if the switching unit is turned off and a negative signal is applied to the second node, the isolation unit electrically isolates the source of the first NMOS transistor from the second node.

16. The system as set forth in claim 15, wherein the isolation unit comprises:
a second NMOS transistor including a drain connected to the source of the first NMOS transistor, and a source connected to the second node;
a third NMOS transistor including a drain connected to a gate of the second NMOS transistor, a source connected to the second node, and a gate to which the second switching signal is applied; and
a second PMOS transistor including a source connected to the gate of the second NMOS transistor, a drain to which the first switching signal is applied, and a gate to which the second switching signal is applied,
wherein the second and third NMOS transistors are connected to the second node through a substrate.

17. The system as set forth in claim 16, wherein the second and third NMOS transistors are formed in a triple well structure.

18. A data input/output method of a system having a USB device and an audio amplifier that share an input/output port, the method comprising:
connecting the input/output port to the audio amplifier;
inputting/outputting an input/output signal of the audio amplifier; and
preventing the input/output signal of the audio amplifier from being transferred to the USB device while inputting/outputting the data.

19. A transmission gate switch, comprising:
a switching circuit to conduct a switching operation between first and second nodes in response to a switching signal; and
an isolation circuit to prevent the switching unit from switching from a predetermined state of operation by an opposite swing in voltage of the first or second node while the switching unit is being turned to the predetermined state of operation.

20. A computer readable recording medium containing codes to perform a data input/output method of a system having a USB device and an audio amplifier that share an input/output port, the method comprising:
connecting the input/output port to the audio amplifier;
inputting/outputting an input/output signal of the audio amplifier; and
preventing the input/output signal of the audio amplifier from being transferred to the USB device while inputting/outputting the data.
